(19) United States
(12) Patent Application Publication
(10) Pub. No.: US 2023/0064496 A1
(43) Pub. Date: Mar. 2, 2023

(54) SPECTRAL DECOMPOSITION METHOD AND APPARATUS WITH BINARY MEMRISTOR CROSSBAR ARRAY

(71) Applicant: Samsung Electronics Co., Ltd., Suwon-si (KR)

(72) Inventors: SEUNGKEUN YOON, Seoul (KR); Hyunsoo KIM, Yongin-si (KR); Sang Joon KIM, Hwaseong-si (KR)

(73) Assignee: Samsung Electronics Co., Ltd., Suwon-si (KR)

(21) Appl. No.: 17/688,198

(22) Filed: Mar. 7, 2022

(30) Foreign Application Priority Data
Aug. 27, 2021 (KR) 10-2021-0114036

(51) Int. Cl. G11C 13/00; H01L 27/24; G06F 17/14; G06G 7/16; G06F 17/16; G10L 19/00

(52) U.S. Cl. CPC G11C 13/0069; H01L 27/2463; G06F 17/141; G06G 7/16; G06F 17/16; G10L 19/00

(57) ABSTRACT

A memristor crossbar array (MCA) circuit includes an input processor configured to receive an input signal corresponding to a predetermined number of input values and to apply the input signal to memristors arranged along input lines, an MCA including the memristors having resistance values based on at least one transformation matrix including binary element values, and an outputter configured to output a frequency component intensity of the input signal based on a signal that is output from each of output lines on which the memristors are arranged, in response to the input signal being applied to the memristors.

### CROSS-REFERENCE TO RELATED APPLICATIONS

This application claims the benefit under 35 USC § 119(a) of Korean Patent Application No. 10-2021-0114036 filed on Aug. 27, 2021, in the Korean Intellectual Property Office, the entire disclosure of which is incorporated herein by reference for all purposes.

### BACKGROUND

### 1. Field

The following description relates to outputting a frequency component intensity of an input signal by applying an input signal to memristors included in a memristor crossbar array (MCA).

### 2. Description of Related Art

A mel-spectrogram or a mel-frequency cepstral coefficient (MFCC) may be output from a preprocessor in a sound recognition process. The mel-spectrogram or the MFCC may be an input to a neural network and consist of a frequency spectrum of an audio signal. To extract the frequency spectrum, spectral decomposition methods, such as, for example, a discrete Fourier transform (DFT) and a fast Fourier transform (FFT), may be used. These existing spectral decomposition methods may generate a discrete time wave of the same sampling rate as that of an audio signal from a continuous wave corresponding to a certain frequency, and then measure the number of frequency components included in the audio signal by measuring correlation or orthogonality with the audio signal. However, in the existing spectral decomposition methods, each sample of the discrete time wave of the frequency may have a real number value or an equivalent high-precision value. To measure the correlation or orthogonality between the generated discrete time wave and a prestored audio signal based on the real number value or the precision value, a high-precision floating-point multiplication needs to be performed, which demands a great amount of calculation. The amount of calculation may increase in proportion to a square of a length of an interval in which a sampling rate or correlation or orthogonality of an audio signal for which spectral decomposition is to be performed is measured. This great amount of calculation may be implemented through a digital signal processor (DSP). However, implementing the great amount of calculation through a memristor crossbar array (MCA) may not be possible because resistance values of memristors need to be adjusted extremely precisely.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a memristor crossbar array (MCA) circuit, including an input processor configured to receive an input signal corresponding to a predetermined number of input values and to apply the input signal to memristors arranged along input lines, an MCA comprising the memristors having resistance values based on at least one transformation matrix comprising binary element values, and an outputter configured to output a frequency component intensity of the input signal based on a signal that is output from each of output lines on which the memristors are arranged, in response to the input signal being applied to the memristors.

One row vector of the at least one transformation matrix may correspond to a frequency component.

The at least one transformation matrix may include a first transformation matrix and a second transformation matrix, and wherein the first transformation matrix and the second transformation matrix may include a number of column vectors corresponding to the predetermined number and a number of row vectors corresponding to the number of frequency components of the input signal.

The MCA circuit may include a memory write circuit configured to set the resistance values of the memristors of the MCA, wherein the memory write circuit may include configured to set a resistance value of a memristor from among the memristors to an element value of a corresponding element of a first transformation matrix, and to set a resistance value of a memristor from among the memristors to an element value of a corresponding element of a second transformation matrix.

The elements of a first reference row vector of the first transformation matrix may have a first value, and an element of a row vector different from the first reference row vector of the first transformation matrix may have a value that is based on element values of a second reference row vector of the first transformation matrix.

A target element of the row vector different from the first reference row vector of the first transformation matrix may have a same value as a value of an element in an order corresponding to a remainder obtained by dividing, by the predetermined number, a product obtained by multiplying a value that indicates a row order of the row vector comprising the target element from among a plurality of row vectors comprising the first transformation matrix and a value indicating an order of the target element in the row vector comprising the target element, from among elements belonging to the second reference row vector of the first transformation matrix.

The elements of a second reference row vector of the second transformation matrix may include elements of a second reference row vector of the first transformation matrix that are shifted by ¼ of the predetermined number.

The target element of a row vector different from a first reference row vector of the second transformation matrix may have a same value as a value of an element in an order corresponding to a remainder obtained by dividing, by the predetermined number, a product obtained by multiplying a value that indicates a row order of the row vector comprising the target element from among a plurality of row vectors comprising the second transformation matrix and a value indicating an order of the target element in the row vector comprising the target element, from among elements belonging to the second reference row vector of the second transformation matrix.

An output line that outputs a signal associated with a real part intensity of a frequency component and an output line that outputs a signal associated with an imaginary part intensity of the frequency component may be adjacent to each other in the MCA.

The outputter may include a plurality of adders configured to add a signal indicating a square of a real part intensity of each frequency component and a signal indicating a square of an imaginary part intensity of the each frequency component from among digital signals corresponding to a square of an output signal of each of the output lines, and to output a signal associated with an intensity of a corresponding frequency component.

The input processor may be configured to apply, to a memristor, a sum signal obtained by adding a first-half input signal of the input signal and a second-half input signal of the input signal and a subtraction signal obtained by subtracting the second-half input signal from the first-half input signal, wherein the at least one transformation matrix may include a third transformation matrix and a fourth transformation matrix, wherein the third transformation matrix and the fourth transformation matrix have a number of column vectors corresponding to half of the predetermined number and have a number of row vectors corresponding to the number of frequency components of the input signal.

The third transformation matrix may be determined based on the row vectors of the first transformation matrix, and the fourth transformation matrix may be determined based on the row vectors of the second transformation matrix.

In anther general aspect, there is provided a processor-implemented method of operating a memristor crossbar array (MCA) circuit, including receiving an input signal corresponding to a predetermined number of input values, and applying the input signal to memristors arranged along input lines, setting resistance values of the memristors included in an MCA based on at least one transformation matrix comprising binary element values, and outputting a frequency component intensity of the input signal based on a signal that is output from each of output lines on which the memristors are arranged, in response to the input signal being applied to the memristors.

The one row vector of the at least one transformation matrix may correspond to a frequency component.

The at least one transformation matrix may include a first transformation matrix and a second transformation matrix, and wherein the first transformation matrix and the second transformation matrix may include a number of column vectors corresponding to the predetermined number and a number of row vectors corresponding to the number of frequency components of the input signal.

The setting of the resistance values of the memristors may include setting a resistance value of a memristor from among the memristors to an element value of a corresponding element of a first transformation matrix, and setting a resistance value of a memristor from among the memristors to an element value of a corresponding element of a second transformation matrix.

The elements of a first reference row vector of the first transformation matrix may have a first value, and an element of a row vector different from the first reference row vector of the first transformation matrix may have a value that is based on element values of a second reference row vector of the first transformation matrix.

A target element of the row vector different from the first reference row vector of the first transformation matrix may have a same value as an element value of an element in an order corresponding to a remainder obtained by dividing, by the predetermined number, a product obtained by multiplying a value that indicates a row order of the row vector comprising the target element from among a plurality of row vectors comprising the first transformation matrix and a value indicating an order of the target element in the row vector comprising the target element, from among elements belonging to the second reference row vector of the first transformation matrix.

The elements of a second reference row vector of the second transformation matrix may include elements of a second reference row vector of the first transformation matrix that are shifted by ¼ of the predetermined number.

The applying to the memristors may include applying, to a memristor, a sum signal obtained by adding a first-half input signal of the input signal and a second-half input signal of the input signal and a subtraction signal obtained by subtracting the second-half input signal from the first-half input signal, wherein the at least one transformation matrix may include a third transformation matrix and a fourth transformation matrix, and wherein the third transformation matrix and the fourth transformation matrix have a number of column vectors corresponding to half of the predetermined number and have a number of row vectors corresponding to the number of frequency components of the input signal.

In another general aspect, there is provided a memristor crossbar array (MCA) circuit, including an MCA comprising memristors arranged along output lines and having resistance values based on at least one transformation matrix, a square circuit configured to square a signal output from each of the output lines, an analog-to-digital converter configured to convert the squared signal output to a digital signal, and a plurality of adders configured to output a signal associated with an intensity of a corresponding frequency component, wherein the at least one transformation matrix including a first transformation matrix and a second transformation matrix, each having a number of column vectors corresponding to a number of input values of an input signal and a number of row vectors corresponding to a number of frequency components of the input signal.

An element corresponding to an i^{th} row and a j^{th} column of the first transformation matrix may be mapped to a memristor arranged on a j^{th} row and an i^{th} column of a first memristor set of the MCA, and an element corresponding to an i^{th} row and a j^{th} column of the second transformation matrix may be mapped to a memristor arranged on a j^{th} row and an (i-1)^{th} column of a second memristor set of the MCA, wherein i may be an integer greater than or equal to 1 and less than or equal to the number of frequency components, and j may be an integer greater than or equal to 1 and less than or equal to the number of the input values.

The at least one transformation matrix may include a third transformation matrix and a fourth transformation matrix each having a number of column vectors corresponding to half of the number of the input values and having a number of row vectors corresponding to the number of frequency components of the input signal.

Other features and aspects will be apparent from the following detailed description, the drawings, and the claims.

### BRIEF DESCRIPTION OF THE DRAWINGS

FIG. 1 illustrates an example of a configuration of a memristor crossbar array (MCA) circuit.

FIG. 2 illustrates an example of an MCA including memristors of which resistance values are determined based on at least one transformation matrix.

FIG. 3 illustrates an example of an MCA circuit including an MCA.

FIGS. 4A and 4B illustrate examples of downsizing an MCA by changing an input signal by an input processor.

FIGS. 5A and 5B illustrate examples of extracting a spectrogram of a frequency component from an audio file using an MCA circuit.

FIGS. 6A and 6B illustrate examples of extracting a spectrogram of a frequency component from an audio file using an MCA circuit.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in the examples described herein may also be referred to as a second member, component, region, layer, or section without departing from the teachings of the examples.

Also, in the description of example embodiments, detailed description of structures or functions that are thereby known after an understanding of the disclosure of the present application will be omitted when it is deemed that such description will cause ambiguous interpretation of the example embodiments. Hereinafter, examples will be described in detail with reference to the accompanying drawings, and like reference numerals in the drawings refer to like elements throughout.

Hereinafter, a method of calculating a spectral decomposition result X of an input signal x using a discrete Fourier transform (DFT) among existing spectral decomposition methods will be described. In an example, an input signal may correspond to a number of input values. For example, the input signal x may be represented by Equation 1 below.

$$x = [ \begin{matrix}{x}_{0} \\ {x}_{1} \\ {x}_{2} \\ ⋮ \\ {x}_{N - 1}\end{matrix} ] \qquad [ Equation 1 ]$$

Referring to Equation 1 above, the input signal x may include signals respectively corresponding to N input values, for example, x₀, x₁, x₂, . . . , and x_{N-1}, and be represented by Equation 1 above. In addition, the spectral decomposition result X of the input signal x may be represented by Equation 2 below.

$$X = [ \begin{matrix}{X}_{0} \\ {X}_{1} \\ {X}_{2} \\ ⋮ \\ {X}_{N - 1}\end{matrix} ] \qquad [ Equation 2 ]$$

Referring to Equation 2 above, the spectral decomposition result X of the input signal x may be represented by an intensity of each frequency component, for example, X₀, X₁, X₂, . . . , and X_{N-1}. The intensity of each frequency component may also be referred to herein as a frequency component intensity for simplicity. In addition, a DFT matrix F for calculating the frequency component intensity X₀, X₁, X₂, . . . , and X_{N-1} may be represented by Equation 3 below.

$$F = [ \begin{matrix}1 & 1 & 1 & 1 & … & 1 \\ 1 & {w}^{1} & {w}^{2 * 1} & {w}^{2 * 1} & … & {w}^{1 ( N - 1 )} \\ 1 & {w}^{2} & {w}^{2 * 2} & {w}^{3 * 2} & … & {w}^{2 ( N - 1 )} \\ 1 & {w}^{3} & {w}^{2 * 3} & {w}^{3 * 3} & … & {w}^{3 ( N - 1 )} \\ ⋮ & ⋮ & ⋮ & ⋮ & ⋱ & ⋮ \\ 1 & {w}^{N - 1} & {w}^{2 ( N - 1 )} & {w}^{3 ( N - 1 )} & … & {w}^{{( N - 1 )}^{2}}\end{matrix} ] \qquad [ Equation 3 ]$$

In an example, the spectral decomposition result X of the input signal x may be calculated as represented by Equation 4 by multiplying the matrix F by the input signal x.

X=Fx [Equation 4]

According to Equation 4 above, each frequency component intensity Xₖ of the spectral decomposition result X may be calculated as represented by Equation 5 below.

$${X}_{k} = {\sum }_{n = 0}^{N - 1} {{x}_{n} ( {e}^{- 2 π i / N} )}^{kn} \\ where k = 0 , 1 , … , N - 1 \qquad [ Equation 5 ]$$

When the DFT matrix F is implemented by a memristor crossbar array (MCA), the input signal x may be applied to the MCA, and a resistance value of each memristor in the MCA of the size of N×N may correspond to an element value of an element in the matrix F to be mapped to a corresponding memristor. The MCA of the size of N×N may be an MCA having N×N memristors.

However, a value of w=e^{-2πi/N} is a complex number and may not be implemented as a resistance value of a memristor. In an example, by dividing it into a real part Fᵣ and an imaginary part Fᵢ, it is possible to implement it by two MCAs of the size of N×N. In this case, memristors included in an MCA of a real part or an imaginary part may need to have a resistance value corresponding to the size of cos(2πkn/N) or sin(2πkn/N). Thus, when the magnitude of N, which is the number of input values corresponding to an input signal, increases, a resistance value of a memristor may need to be finely adjusted.

By grouping together elements having the same absolute value in one column of the DFT matrix F and dispersing memristors to columns by the number of groups, it is possible to implement the DFT matrix F by a binary MCA without a fine adjustment of a resistance value of the memristors. The binary MCA may be an MCA in which memristors have one resistance value between two resistance values.

However, in such a case, to implement the DFT matrix F, an MCA of the size considerably greater than the size of N×N may be required, and a circuit for finely adjusting an analog sum signal for each column of the MCA may be additionally required. For example, when elements of the matrix F are grouped by a unit of cos(2π/N), N/4 groups, for example, 1, ±cos(2π/N), . . . , and ±cos(2π(N/4-1)/N), may be needed. The number of columns of an MCA corresponds to the number of frequency components to be extracted, and thus a binary MCA of the size of

$$N \times ( - \frac{k \times N}{4} )$$

for each of a real part and an imaginary part may be needed to extract k frequencies.

Also, similar issues described above may arise even in a case of performing spectral decomposition on an input signal through a fast Fourier transform (FFT) which is one of the existing spectral decomposition methods. The FFT may transform the matrix F into a combination of small-sized matrices and a sparse matrix, thereby reducing a total amount of calculation used for spectral decomposition of an input signal. However, there may still be the same issue of having to finely adjust a resistance value of a memristor. As described above, in a process of decomposing a spectrum of an input signal using the DFT or the FFT which is one of the existing spectral decomposition methods, a transformation matrix F used for spectral decomposition may be generated based on a cosine wave and a sine wave, and an issue of finely adjusting a resistance value may thus occur.

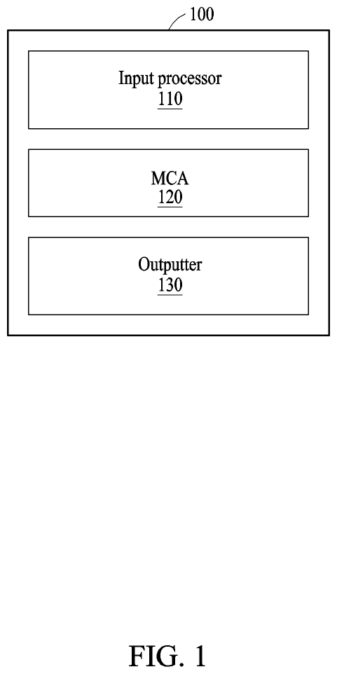

FIG. 1 illustrates an example of a configuration of an MCA circuit.

Referring to FIG. 1, an MCA circuit 100 may include an input processor 110, an MCA 120, and an outputter 130.

The input processor 110 may receive an input signal. The input signal may correspond to a number of input values. In an example, the number of input values may be predetermined. The input signal may include signals respectively corresponding to the input values. For example, when the input processor 110 receives an audio signal as the input signal, one frame may be received as the input signal. In this example, the predetermined number may represent a frame length of one frame, and as many samples of the audio signal as the frame length may be included in the one frame. That is, the input values corresponding to the input signal may be input values corresponding to a number of samples included in a frame. The input processor 110 may receive the input signal corresponding to the number of input values and apply the received input signal to memristors arranged along input lines.

The MCA 120 may include memristors of which resistance values are set based on at least one transformation matrix including binary element values. The MCA 120 may be a binary MCA. Although to be described later, each of the memristors included in the MCA 120 may have a resistance value set as one of a first resistance value and a second resistance value. In addition, the memristors may be arranged along output lines included in the MCA 120, and an output line may output a signal associated with an intensity of one frequency component.

The outputter 130 may output a frequency component intensity of the input signal based on a signal that is output from each of the output lines on which the memristors are arranged, in response to the input signal being applied to the memristors of the MCA 120.

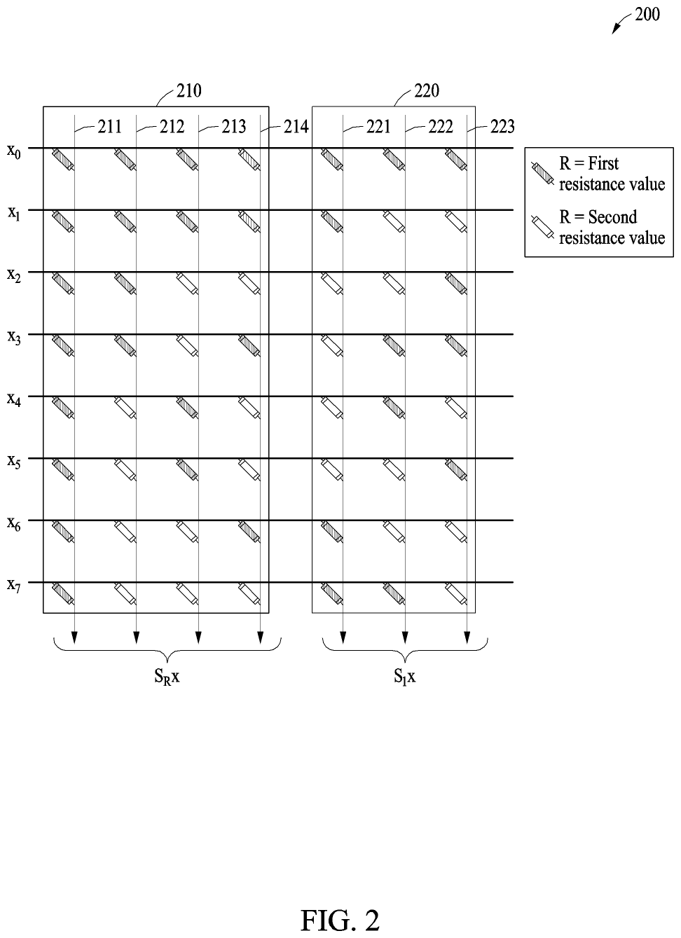

FIG. 2 illustrates an example of an MCA including memristors of which resistance values are determined based on at least one transformation matrix.

A binary square wave-based transformation matrix S may be represented as Equation 6 below. Each of row vectors of the transformation matrix S may indicate a binary square wave-based vector.

$$S = [ \begin{matrix}{s}_{0 , 0} & {s}_{0 , 1} & … & {s}_{1 , N - 1} \\ {s}_{1 , 0} & {s}_{1 , 1} & … & {s}_{1 , N - 1} \\ ⋮ & ⋮ & ⋱ & ⋮ \\ {s}_{m , 0} & {s}_{m , 1} & … & {s}_{m , N - 1}\end{matrix} ] where {s}_{a , b} = 1 or - 1 \qquad [ Equation 6 ]$$

In Equation 6 above, m may be an integer greater than or equal to 1 and less than or equal to N−1. a may be an integer greater than or equal to 1 and less than or equal to m, and b may be an integer greater than or equal to 1 and less than or equal to N−1. Referring to Equation 6 above, an element value of the transformation matrix S may be one of 1 and −1. In an example, one row vector constituting a transformation matrix may correspond to one frequency component.

As described above, a resistance value of memristors included in an MCA 200 may be set based on at least one transformation matrix. The at least one transformation matrix may include a first transformation matrix and a second transformation matrix. The first transformation matrix and the second transformation matrix may have column vectors of which the number corresponds to a number of input values corresponding to an input signal, and have row vectors of which the number corresponds to the number of frequency components of the input signal. In an example, the number of input values are predetermined. The first transformation matrix and the second transformation matrix may have a similar form to that of the transformation matrix S. For example, each of the first transformation matrix and the second transformation matrix may have a form of the transformation matrix S in which m+1 is set as the number of frequency components of the input signal in Equation 6. The predetermined number is indicated herein as N and the number of frequency components is indicated herein as k.

In an example, an MCA circuit may further include a memory write circuit configured to set a resistance value of memristors included in an MCA. The memory write circuit may set a resistance value of a memristor by applying a voltage or current to both ends of the memristor. For example, the memory write circuit may set a resistance value of a memristor to be a first resistance value corresponding to an element value of 1, or a second resistance value corresponding to an element value of −1.

In an example, the memory write circuit may set a resistance value corresponding to an element value of an element of the first transformation matrix to be a resistance value of a memristor mapped to the element based on the first transformation matrix. Similarly, the memory write circuit may set a resistance value corresponding to an element value of an element of the second transformation matrix to be a resistance value of a memristor mapped to the element based on the second transformation matrix.

For example, as illustrated in FIG. 2, the MCA 200 may include a memristor set 210 including memristors of which a resistance value is determined based on the first transformation matrix, and a memristor set 220 including memristors of which a resistance value is determined based the second transformation matrix. The memristor set 210 of which the resistance value is determined based on the first transformation matrix may include N×k memristors, and the memristor set 220 of which the resistance value is determined based on the second transformation matrix may include N×(k−1) memristors.

For example, in the example of FIG. 2, N which is a predetermined number is 8, and k which is the number of frequency components of an input signal is 4. In this example, each of the first transformation matrix and the second transformation matrix may be in a form of a 4×8 matrix. In this example, the memristor set 210 of which the resistance value is determined based on the first transformation matrix may include 8×4 memristors, and the memristor set 220 of which the resistance value is determined based on the second transformation matrix may include 8×3 memristors.

In an example, an element corresponding to an ith row and a jth column of the first transformation matrix and a memristor arranged on a jth row and an ith column of the memristor set 210 of the MCA 200 may be mapped to each other. In this example, i may be an integer greater than or equal to 1 and less than or equal to k, and j may be an integer greater than or equal to 1 and less than or equal to N. In this example, the memory write circuit may set a resistance value of a memristor corresponding to an element value of each element of the first transformation matrix to be a resistance value of a memristor mapped to a corresponding element.

For example, referring to FIG. 2, when an element value of an element corresponding to a third row and a fourth column of the first transformation matrix is −1, a resistance value of a memristor arranged on a fourth row and a third column of the memristor set 210 may be set to be a second resistance value corresponding to −1.

Similarly, an element corresponding to an ith row and a jth column of the second transformation matrix and a memristor arranged on a jth row and an (i-1)th column of the memristor set 220 of the MCA 200 may be mapped to each other. The memristor write circuit may set a resistance value corresponding to an element value of each element of the second transformation matrix to be a resistance value of a memristor mapped to a corresponding element.

For example, referring to FIG. 2, when an element value of an element corresponding to a second row and a seventh column of the second transformation matrix is 1, a resistance value of a memristor arranged on a seventh row and a first column of the memristor set 220 may be set to be a first resistance value corresponding to 1.

Hereinafter, a detailed method of calculating the first transformation matrix and the second transformation matrix will be described.

In an example, elements of a first reference row vector of the first transformation matrix may have the first value, and an element value of a row vector different from the first reference row vector among a plurality of rows of the first transformation matrix may have a value that is based on element values of a second reference row vector of the first transformation matrix.

The first value is described herein as 1 and the second value is described herein as −1. However, the first value and the second value are not limited thereto, and the first value may be −1 and the second value may be 1. In addition, the first reference row vector may be a row vector of a first row, and the second reference row vector may be a row vector of a second row.

For example, when row vectors of a first transformation matrix S_{R} are S_{R}[0], S_{R}[1], S_{R}[2], . . . , and S_{R}[N−1], an nth row vector of the first transformation matrix S_{R} may be represented as S_{R}[n]. In this example, elements of a first reference row vector S_{R}[0] of the first transformation matrix SR may have the first value which is 1. In addition, a first half of elements of a second reference row vector S_{R}[1] of the first transformation matrix S_{R} may all have the first value which is 1, and a remaining half of the elements may all have the second value which is −1. Equation 7 below may represent examples of row vectors S_{R}[0] and S_{R}[1] when N which is a predetermined number of input values corresponding to an input signal is 8.

S_{R}[0]=[1 1 1 1 1 1 1 1]

S_{R}[1]=[1 1 1 1 −1 −1 −1 −1] [Equation 7]

When N is odd, elements from an element in a first order of the second reference row vector S_{R}[1] to an element in a

$$\frac{N - 1}{2}$$

th order of the second reference row vector S_{R}[1] may have the first value which is 1, and remaining elements may all have the second value which is −1. However, examples are not limited thereto. For example, when N is odd, elements from the element in the first order of the second reference row vector S_{R}[1] to an element in a

$$\frac{N + 1}{2}$$

th order of the second reference row vector S_{R}[1] may have the first value which is 1, and remaining elements may have the second value which is −1.

An element value of a row vector different from the first reference row vector S_{R}[0] from among a plurality of rows of the first transformation matrix S_{R} may have a value that is based on element values of the second reference row vector S_{R}[1] of the first transformation matrix S_{R}. In an example, a target element of a row vector different from the first reference row vector S_{R}[0] of the first transformation matrix S_{R} may have the same value as an element value of an element in an order corresponding to a remainder obtained by dividing, by the predetermined number, a product of a multiplication between a value indicating a row order of the row vector including the target element among a plurality of row vectors included in the first transformation matrix S_{R} and a value indicating an order of the target element in the row vector including the target element, among elements belonging to the second reference row vector S_{R}[1].

That is, another row vector S_{R}[p] may be calculated based on the second reference row vector S_{R}[1]. Here, p may be an integer greater than or equal to 2 and less than or equal to k. A qth (q=0, 1, . . . , N−1) element, which is a target element of the row vector S_{R}[p], may have the same value as an element value in an order corresponding to a remainder obtained by dividing, by N, (q×p) among elements belonging to the second reference row vector S_{R}[1]. Also, p may represent a value indicating a row order of the row vector S_{R}[p] among a plurality of row vectors of the first transformation matrix S_{R}, and q may represent a value indicating an order of the target element in the row vector S_{R}[p].

Hereinafter, an example of calculating a fourth row vector S_{R}[3] of the first transformation matrix S_{R} when N is 8 will be described. In this example, a 0th element of the row vector S_{R}[3] may have the same value as an element value 1 of an element in a 0th order corresponding to 0 which is a remainder obtained by dividing, by 8, an element 0×3 among the elements belonging to the second reference row vector S_{R}[1]. A third element of the row vector S_{R}[3] may have the same value as an element value 1 of an element in a first order corresponding to 1 which is a remainder obtained by dividing, by 8, an element 3×3 among the elements belonging to the second reference row vector S_{R}[1]. Equation 8 below represents an example of the first transformation matrix SR in a case in which N is 8 and k is 4.

$${S}_{R} = [ \begin{matrix}1 & 1 & 1 & 1 & 1 & 1 & 1 & 1 \\ 1 & 1 & 1 & 1 & - 1 & - 1 & - 1 & - 1 \\ 1 & 1 & - 1 & - 1 & 1 & 1 & - 1 & - 1 \\ 1 & 1 & - 1 & 1 & - 1 & - 1 & 1 & - 1\end{matrix} ] \qquad [ Equation 8 ]$$

A second transformation matrix S_{I} may be generated based on the first transformation matrix S_{R}. First, elements of a first reference row vector S_{I}[0] of the second c transformation matrix S_{I} may have a third value 0 which is different from the first value 1 and the second value −1.

The first reference row vector S_{I}[0] of the second transformation matrix S_{I} may not be used to set a resistance value of memristors, but a remaining row vector of the second transformation matrix S_{I} may be used to set the resistance value of the memristors.

A second reference row vector S_{I}[1] of the second transformation matrix S_{I} may have elements that are shifted from elements of the second reference row vector S_{R}[1] of the first transformation matrix S_{R} by ¼ of the predetermined number N. A relationship between the second reference row vector S_{R}[1] of the first transformation matrix S_{R} and the second reference row vector S_{I}[1] of the second transformation matrix S_{I} may reflect therein a relationship between an imaginary part representing a sine function in a process of a DFT and a real part representing a cosine function in the process of the DFT.

Equation 9 below represents examples of the first reference row vector S_{I}[0] and the second reference row vector S_{I}[1] of the second transformation matrix Si in a case in which N is 8. In this case, the second reference row vector S_{R}[1] of the first transformation matrix S_{R} is assumed to be the same as represented in Equation 7 above.

S_{I}[0]=[0 0 0 0 0 0 0 0]

S_{I}[1]=[1 1 −1 −1 −1 −1 1 1] [Equation 9]

Equation 9 represents an example where the second reference row vector S_{I}[1] of the second transformation matrix S_{I} has elements obtained as elements of the of the second reference row vector S_{R}[1] of the first transformation matrix SR are shifted to the left by N/4 (=2).

A target element of a row vector different from the first reference row vector S_{I}[0] of the second transformation matrix S_{I} may have the same value as an element value in an order corresponding to a remainder obtained by dividing, by the predetermined number, a product of a multiplication between a value indicating a row order of the row vector including the target element among row vectors included in the second transformation matrix S_{I} and a value indicating an order of the target element in the row vector including the target element, among elements belonging to the second reference row vector S_{I}[1] of the second transformation matrix S_{I}.

For example, another row vector S_{I}[r] may be calculated based on the second reference row vector S_{I}[1]. In this example, r may be an integer greater than or equal to 2 and less than or equal to k. An sth element (s=0, 1, . . . , N−1), which is a target element of the row vector S_{I}[r], may have the same value as an element value of an element in an order corresponding to a remainder obtained by dividing, by N, an element (s×r) among elements belonging to the second reference row vector S_{I}[1]. In this example, r may represent a value indicating a row order of the row vector S_{I}[r] among row vectors of the second transformation matrix S_{I}, and s may represent a value indicating an order of the target element in the row vector S_{I}[r]. This is the same as the foregoing method of calculating a target element of a row vector different from a first reference row vector using a second reference row vector in a first transformation matrix.

Equation 10 below represents an example of the second transformation matrix S_{I} in a case in which N is 8 and k (the number of frequency components) is 4.

$${S}_{I} = [ \begin{matrix}0 & 0 & 0 & 0 & 0 & 0 & 0 & 0 \\ 1 & 1 & - 1 & - 1 & - 1 & - 1 & 1 & 1 \\ 1 & - 1 & - 1 & 1 & 1 & - 1 & - 1 & 1 \\ 1 & - 1 & 1 & 1 & - 1 & 1 & - 1 & - 1\end{matrix} ] \qquad [ Equation 10 ]$$

In an example, k which is the number of frequency components has a value that is less than or equal to half of N which is the predetermined number. More specifically, the number k of frequency components for performing spectral decomposition on an input signal may need to have a value that is less than or equal to N/2. One row vector of the first transformation matrix S_{R} and the second transformation matrix S_{I} may correspond to one frequency component. A row vector S_{R}[N−i] of the first transformation matrix S_{R} simply represents a row vector to which elements of a row vector S_{R}[i] are shifted, and thus a frequency component corresponding to the row vector SR[N−i] and a frequency component corresponding to the row vector S_{R}[i] may be the same. Similarly, a row vector S_{I}[N−i] in the second transformation matrix S_{I} simply represents a row vector to which elements of a row vector S_{I}[i] are shifted, and thus a frequency component corresponding to the row vector S_{I}[N−i] and a frequency component corresponding to the row vector S_{I}[i] may be the same. Thus, because each of the first transformation matrix S_{R} and the second transformation matrix S_{I} has a row vector corresponding to maximally N/2 frequency components, the number k of frequency components may be determined to be less than or equal to N/2.

Equation 11 below may be used to calculate Z representing a frequency component intensity of an input signal using the first transformation matrix S_{R} and the second transformation matrix S_{I}.

Z²=|S_{R}x|²+|S₁x|² [Equation 11]

Referring back to FIG. 2, since both the first transformation matrix S_{R} and the second transformation matrix S_{I} have binary element values, for example, 1 or −1, each of memristors included in the MCA 200 illustrated in FIG. 2 may have a first resistance value corresponding to the first value or a second resistance value corresponding to the second value. In the example of FIG. 2, illustrated is the MCA 200 in a case in which the predetermined number N is 8 and the number k of frequency components is 4. A reference value of memristors arranged on one output line for each of four output lines 211, 212, 213, and 214 on the left side of the MCA 200 may be set based on an element value of one row of the first transformation matrix S_{R} in Equation 8. A reference value of memristors arranged on one output line for each of three output lines 221, 222, and 223 on the right side of the MCA 200 may be set based on an element value of one row among remaining three rows excluding a first reference row of the second transformation matrix S_{I} in Equation 10. Elements of the first reference row vector S_{I}[0](e.g., a first row vector) of the second transformation matrix S_{I} have the third value which is 0, and thus a resistance value of memristors included in the MCA 200 may not be set.

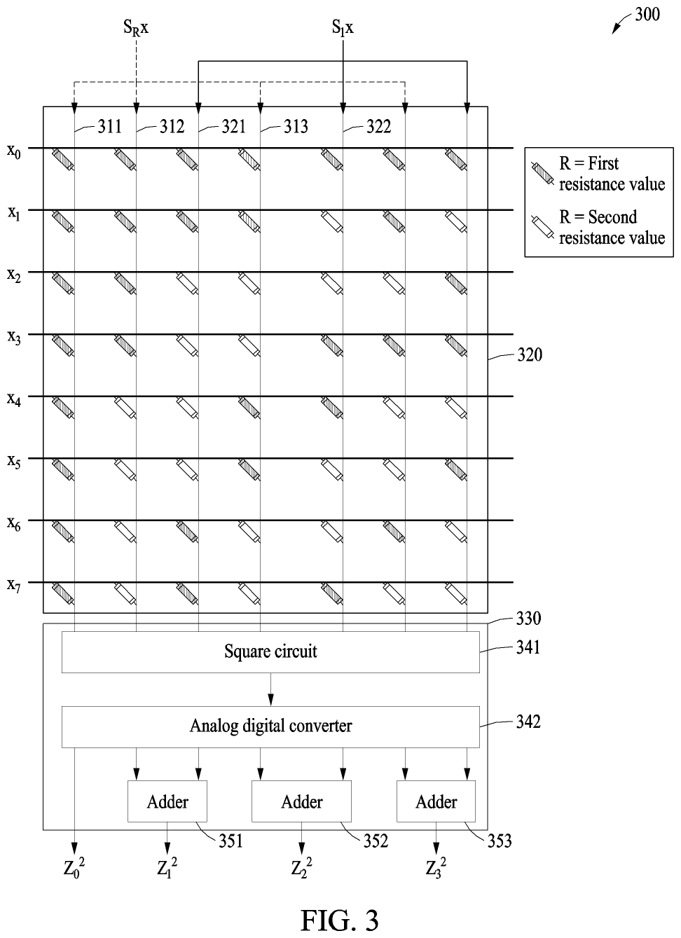

FIG. 3 illustrates an example of an MCA circuit including an MCA.

An input signal x to be applied to an MCA circuit 300 may be commonly input to output lines, and thus it may not be a problem if an output line indicated by a row vector of a first transformation matrix S_{R} and an output line indicated by a row vector of a second transformation matrix S_{I} change each other. In an example, each output line of an MCA 320 may output a signal associated with an intensity of one frequency component. Among output lines on which memristors included in the MCA 320 are arranged, an output line on which memristors of which a resistance value is determined based on the first transformation matrix S_{R} are arranged may output a signal of a real part intensity of a frequency component corresponding to the output line. For example, an output line 311 on which memristors of which a resistance value is set based on a first reference row vector S_{R}[0] of the first transformation matrix S_{R} are arranged may output a signal of a real part intensity of a frequency component corresponding to the first reference row vector S_{R}[0]. For another example, an output line 312 on which memristors of which a resistance value is set based on a second reference row vector S_{R}[1]of the first transformation matrix S_{R} are arranged may output a signal of a real part intensity of a frequency component corresponding to the second reference row vector S_{R}[1].

In addition, among the output lines on which the memristors included in the MCA 320 are arranged, an output line on which memristors of which a resistance value is determined based on the second transformation matrix S_{I} may output a signal associated with an imaginary part intensity of a frequency component corresponding to the output line. For example, an output line 321 on which memristors of which a resistance value is set based on a first reference row vector S_{I}[0] of the second transformation matrix S_{I} are arranged may output a signal of an imaginary part intensity of a frequency component corresponding to the first reference row vector S_{I}[0]. For another example, an output line 322 on which memristors of which a resistance value is set based on a second reference row vector S_{I}[1] of the second transformation matrix S_{I} are arranged may output a signal of an imaginary part intensity of a frequency component corresponding to the second reference row vector S_{I}[1].

In these examples, a final intensity of one frequency component may be calculated using a real part intensity of the frequency component and an imaginary part intensity of the frequency component. More specifically, a sum of a square of the real part intensity of the frequency component and a square of the imaginary part intensity of the frequency component may be the same value as a square of the final intensity of the frequency component.

In an example, an output line that outputs a signal of a real part intensity of one frequency component and an output line that outputs a signal of the same intensity of the frequency component may be arranged to be adjacent to each other in the MCA 320. That is, a final intensity of one frequency component may be calculated based on a signal of a real part intensity of the frequency component and a signal of an imaginary part intensity of the frequency component, and it may thus be effective that an output line outputting the signal of the real part intensity of the frequency component and an output line outputting the signal of the imaginary part intensity of the frequency component are arranged to be adjacent to each other. For example, as illustrated in FIG. 3, the output line 312 that outputs a signal of a real part intensity of a frequency component corresponding to the second reference row vector S_{R}[1] of the first transformation matrix S_{R} and the output line 321 that outputs a signal of a real part intensity of a frequency component corresponding to the second reference row vector S_{I}[1] of the second transformation matrix S_{I} may be arranged adjacent to each other. A frequency component corresponding to a row vector of the first transformation matrix S_{R} and a frequency component corresponding to a row vector in the same order as the row vector in the second transformation matrix S_{I} may be the same. For another example, as illustrated in FIG. 3, an output line 313 that outputs a signal of a real part intensity of a frequency component corresponding to a row vector S_{R}[2] in a third order of the first transformation matrix S_{R} and an output line 322 that outputs a signal of an imaginary part intensity of a frequency component corresponding to a row vector S_{I}[2] in a third order of the second transformation matrix S_{I} may be arranged to be adjacent to each other.

In addition, the frequency component corresponding to the first reference row vector S_{R}[0] of the first transformation matrix S_{R} may correspond to a frequency component of 0 which corresponds to a direct current (DC) component, and thus the output line 311 corresponding to the first reference row vector S_{R}[0] may immediately output a signal of a final intensity of the frequency component.

In an example, the MCA circuit 300 may include an outputter 330. The outputter 330 may include a plurality of adders 351, 352, and 353 that outputs a signal of a final intensity by adding a signal indicating a square of a real part intensity of each frequency component and a signal indicating a square of an imaginary part intensity of each frequency component, among digital signals corresponding to respective squares of output signals of output lines. More specifically, the adders 351, 352, and 353 may output a signal of a square of a final intensity by adding a square of a real part intensity of a frequency component and a square of an imaginary part intensity of the frequency component.

In an example, as illustrated in FIG. 3, the outputter 330 may include a square circuit 341 configured to square a signal output from the output lines and an analog-to-digital converter (ADC) 342 configured to convert an analog signal output from the square circuit 341 to a digital signal.

In another example, the orders of the square circuit 341 and the ADC 342 may be reversed. For example, the outputter 330 may include an ADC configured to convert an analog signal output from the output lines to a digital signal and a square circuit configured to square the digital signal output from the ADC.

Thus, the MCA circuit 300 may apply, to the outputter 330, a signal output from the output lines, and the outputter 330 may output a final intensity of each frequency component of an input signal. In such a case, the MCA 320 included in the MCA circuit 300 may have the size of N×(2k−1). That is, each of the first transformation matrix S_{R} and the second transformation matrix S_{I} may have a matrix of the size of N×k, and the first reference row vector S_{I}[0] of the second transformation matrix S_{I} may not be used to set a resistance value of memristors. Thus, the MCA 320 may include a total of N×(2k−1) memristors. For example, when N is 8 and k is 4 as illustrated in FIG. 3, the size of the MCA 320 may be 8×7.

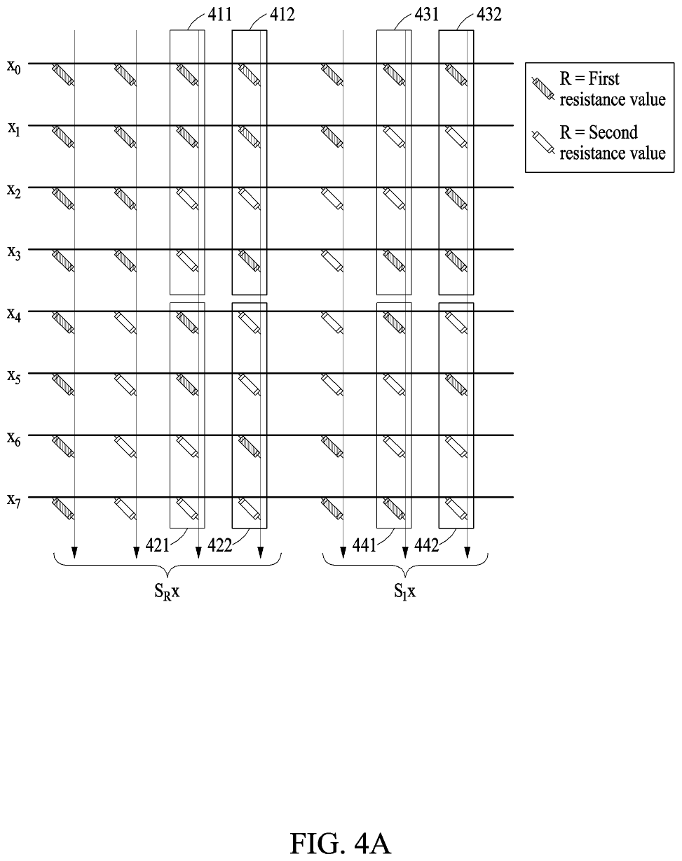

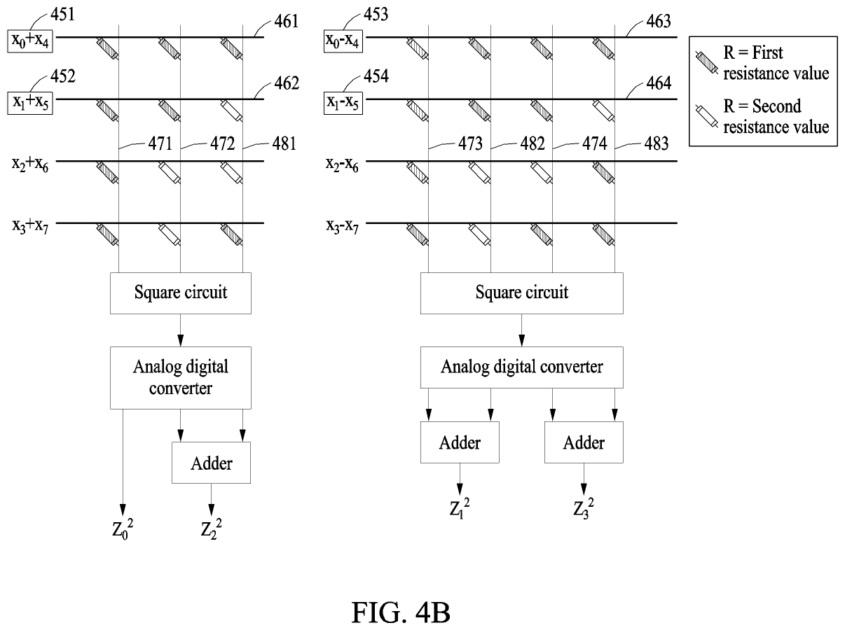

FIGS. 4A and 4B illustrate examples of downsizing an MCA by changing an input signal by an input processor.

In an example, an input processor may apply, to a memristor, a sum signal obtained by adding a first-half input signal of an input signal and a second-half input signal of the input signal and a subtraction signal obtained by subtracting the second-half input signal from the first-half input signal. In an example, a resistance value of memristors may be set based on at least one transformation matrix including binary element values. The at least one transformation matrix may include a third transformation matrix and a fourth transformation matrix. The third transformation matrix and the fourth transformation matrix may have a number of column vectors corresponding to half a predetermined number of input values corresponding to the input signal and may have a number of row vectors corresponding to the number of frequency components of the input signal. The third transformation matrix may be determined based on row vectors of a first transformation matrix, and the fourth transformation matrix may be determined based on row vectors of a second transformation matrix.

For example, an element value of a qth element (q=0, 1, . . . , N−1) of a row vector S_{R}[p] of a first transformation matrix SR may be the same as an element value in an order corresponding to a remainder obtained by dividing, by N, (q×p) among elements of a second reference row vector S_{R}[1] of the first transformation matrix S_{R}. An element value of a

$$q + \frac{N}{2} th$$

element of the row vector S_{R}[p] may be the same as an element value in an order corresponding to a remainder obtained by dividing, by N,

$$q \times p + \frac{N}{2} \times p$$

of the second reference row vector S_{R}[1].

In this example, when a value of p is odd, the

$$q + \frac{N}{2} th$$

element of the row vector S_{R}[p] may have the element value in the order corresponding to the remainder obtained by dividing, by N,

$$q \times p + \frac{N}{2} \times p$$

among the elements of the second reference row vector S_{R}[1]. Here, first-half elements of the second reference row vector S_{R}[1] may have a first value which is 1, and remaining-half elements of the second reference row vector S_{R}[1]may have a second value which is −1. In addition, since the value of p is odd, the

$$q + \frac{N}{2} th$$

element of the row vector S_{R}[p] may have the element value different from the element value in the order corresponding to the remainder obtained by dividing (q×p) of the row vector S_{R}[1] by N. Thus, the

$$q + \frac{N}{2} th$$

element of the row vector S_{R}[p] may have an element value different from a qth element of the row vector S_{R}[p].

In contrast, when the value of p is even, the

$$q + \frac{N}{2} th$$

element of the row vector S_{R}[p] may have an element value in an order corresponding to a remainder obtained by dividing, by N,

$$q \times p + \frac{N}{2} \times p$$

among the elements of the second reference row vector S_{R}[1]. Since the value of p is even, the

$$q + \frac{N}{2} th$$

element of the row vector S_{R}[p] may have an element value different from the element value in the order corresponding to the remainder obtained by dividing (q×p) of the row vector S_{R}[1] by N. Thus, the

$$q + \frac{N}{2} th$$

element of the row vector S_{R}[p] may have the same element value as the qth element of the row vector S_{R}[p].

For example, referring to FIG. 4A, the value p that indicates an order of a third row vector S_{R}[2] of the first transformation matrix S_{R} is 2, and thus the value p is even. Thus, memristors included in a memristor set 411 of which a resistance value is set based on an element value of first-half elements of the third row vector S_{R}[2] and memristors included in a memristor set 421 of which a resistance value is set based on an element value of remaining elements of the third row vector S_{R}[2] may have resistance values corresponding to each other. For example, when the memristors included in the memristor set 411 sequentially have a first resistance value, the first resistance value, a second resistance value, and the second resistance value, the memristors included in the memristor set 421 may also sequentially have the first resistance value, the first resistance value, the second resistance value, and the second resistance value. For another example, the value p that indicates an order of a fourth row vector S_{R}[3] of the first transformation matrix S_{R} is 3, and thus the value p is odd. Thus, memristors included in a memristor set 412 of which a resistance value is set based on an element value of first-half elements of the fourth row vector S_{R}[3] and memristors included in a memristor set 422 of which a resistance value is set based on an element value of remaining elements of the fourth row vector S_{R}[3] may have resistance values opposite to each other. For example, when the memristors included in the memristor set 412 sequentially have the first resistance value, the first resistance value, the second resistance value, and the first resistance value, the memristors included in the memristor set 422 may sequentially have the second resistance value, the second resistance value, the first resistance value, and the second resistance value.

Similarly, the value q that indicates an order of a third row vector S_{I}[2] of the second transformation matrix S_{I} is 2, and thus the value q is even. Thus, memristors included in a memristor set 431 of which a resistance value is set based on an element value of first-half elements of the third row vector S_{I}[2] and memristors included in a memristor set 441 of which a resistance value is set based on an element value of remaining elements of the third row vector S_{I}[2] may have resistance values corresponding to each other. In addition, the value q that indicates an order of a fourth row vector S_{I}[3] of the second transformation matrix S_{I} is 3, and thus the value q is odd. Thus, memristors included in a memristor set 432 of which a resistance value is set based on an element value of first-half elements of the fourth row vector S_{I}[3] and memristors included in a memristor set 442 of which a resistance value is set based on an element value of remaining elements of the fourth row vector S_{I}[3] may have resistance values opposite to each other.

Thus, row vectors of a first transformation matrix may be represented only by first-half elements of each row vector. By defining, as S_{R/2}[p], row vectors including only first-half elements of S_{R}[p], a relationship between S_{R}[p] and S_{R/2}[p] may be represented by Equation 12 below.

S_{R}[p]={S_{R/2}[p], S_{R/2}[p]}if p is even

S_{R}[p]={S_{R/2}[p], −S_{R/2}[p]}if p is odd [Equation 12]

That is, the first transformation matrix S_{R} may be represented by being downsized to a third transformation matrix S_{R/2}.

Similarly, the second transformation matrix S_{I} may be represented by being downsized to a fourth transformation matrix S_{I/2}. A relationship between S_{I}[q] and S_{I/2}[q] may be represented by Equation 13 below.

S_{I}[q]={S_{I/2}[q], S_{I/2}[q]}if q is even

S_{I}[q]={S_{I/2}[q], −S_{I/2}[p]}if q is odd [Equation 13]

Further, a predetermined number of input values corresponding to an input signal may include first-half input values and second-half input values. For example, when predetermined input values corresponding to an input signal x are x₀, x₁, x₂, . . . , and x_{N-1}, first-half input values x_{H} may be a first half of the input values and second-half input values x_{T} may be a remaining half of the input values. In this example, Z representing a final intensity of each frequency component of the input signal may be represented by Equation 14 below.

Z[k]²=|S_{R/2}[k](x_{H}+x_{T})|²+|S_{I/2}[k](x_{H}+x_{T})|² if k is even

Z[k]²=|S_{R/2}[k](x_{H}−x_{T})|²+|S_{I/2}[k](x_{H}−x_{T})|² if k is odd [Equation 14]

An MCA may be generated using the third transformation matrix S_{R/2} and the fourth transformation matrix S_{I/2}, an input value x_{H}+x_{T} corresponding to a sum obtained by adding the first-half input values x_{H} and the second-half input values x_{T}, and an input value x_{H}−x_{T} corresponding to a value obtained by subtracting the second-half input values x_{T} from the first-half input values x_{H}.

In an example, the input processor may apply, to a memristor, a sum signal obtained by adding a first-half input signal of an input signal and a second-half input signal of the input signal and a subtraction signal obtained by subtracting the second-half input signal from the first-half input signal. In this example, the first-half input signal of the input signal may represent a signal corresponding to first-half input values xH, and the second-half input signal of the input signal may represent a signal corresponding to second-half input values x_{T}.

For example, the input processor may apply, to one input line, a signal corresponding to a sum obtained by adding an input value in a dth order and an input value in a

$$d + \frac{N}{2} th$$

order from among a predetermined number of input values corresponding to an input signal, and apply, to another input line, a signal corresponding to a value obtained by subtracting the input value in the

$$d + \frac{N}{2} th$$

order from the input value in the dth order. In this example, d may be an integer greater than or equal to 0 and less than N/2.

In the example of FIG. 4B, a predetermined number N of input signals corresponding to an input signal may be 8. The input signal may be a signal corresponding to the input values, for example, x₀, x₁, . . . , and x₇. In this example, a first-half input signal of the input signal may be a signal corresponding to input values x₀, x₁, x₂, and x₃, and a second-half input signal of the input signal may be a signal corresponding to remaining input values x₄, x₅, x₆, and x₇. In this example, the input processor may apply a sum signal obtained by adding the first-half input signal and the second-half input signal to memristors arranged along input lines in the MCA. Similarly, the input processor may apply a subtraction signal obtained by subtracting the second-half input signal from the first-half input signal to memristors arranged along other input lines in the MCA.

In the example of FIG. 4B, the input processor may apply a signal corresponding to a value 451 obtained by adding an input value x₀ and an input value x₄ to memristors arranged along an input line 461, and apply a signal corresponding to a value 453 obtained by subtracting the input value x₄ from the input value x₀ to memristors arranged along an input line 463. In addition, the input processor may apply a signal corresponding to a value 452 obtained by adding an input value x₁ and an input value x₅ to memristors arranged along an input line 462, and apply a signal corresponding to a value 454 obtained by subtracting the input value x₅ from the input value x₁ to memristors arranged along an input line 464.

When the input processor applies a changed input signal to memristors by changing the input signal, a resistance value of the memristors may be set based on the third transformation matrix S_{R/2} and the fourth transformation matrix S_{I/2}. That is, at least one transformation matrix may include the third transformation matrix S_{R/2} and the fourth transformation matrix S_{I/2}. The third transformation matrix S_{R/2} and the fourth transformation matrix S_{I/2} may have column vectors corresponding to half (N/2) of the predetermined number N and row vectors corresponding to the number k of frequency components. However, when N is odd, the third transformation matrix S_{R/2} and the fourth transformation matrix S_{I/2} may have column vectors corresponding to

$$\frac{N + 1}{2}$$

and row vectors corresponding to the number k of frequency components.

A resistance value of memristors included in the MCA may be set based on a third transformation matrix and a fourth transformation matrix, in the same manner as a resistance value of the memristors is set based on a first transformation matrix and a second transformation matrix. A memory write circuit may set a resistance value corresponding to an element value of an element of the third transformation matrix to be a resistance value of a memristor mapped to the element, and set a resistance value corresponding to an element value of an element of the fourth transformation matrix to be a resistance value of a memristor mapped to the element.

In the example of FIG. 4B, it is assumed that a predetermined number N of input values corresponding to an input signal is 8, and the number k of frequency components is 4. A first transformation matrix and a second transformation matrix are assumed to have matrices according to Equations 8 and 10, respectively. In this example, a third transformation matrix and a fourth transformation matrix may have matrices represented as Equations 15 and 16, respectively.

$${S}_{R / 2} = [ \begin{matrix}1 & 1 & 1 & 1 \\ 1 & 1 & 1 & 1 \\ 1 & 1 & - 1 & - 1 \\ 1 & 1 & - 1 & 1\end{matrix} ] \qquad [ Equation 15 ]$$

$${S}_{I / 2} = [ \begin{matrix}0 & 0 & 0 & 0 \\ 1 & 1 & - 1 & - 1 \\ 1 & - 1 & - 1 & 1 \\ 1 & - 1 & 1 & 1\end{matrix} ] \qquad [ Equation 16 ]$$

Referring to FIG. 4B, a resistance value of memristors arranged along an output line 471 may be set based on a first row vector of the third transformation matrix S_{R/2}, and a resistance value of memristors arranged along an output line 472 may be set based on a second row vector of the third transformation matrix S_{R/2}. In addition, a resistance value of memristors arranged along an output line 473 may be set based on a third row vector of the third transformation matrix S_{R/2}, and a resistance value of memristors arranged along an output line 474 may be set based on a fourth row vector of the third transformation matrix SR_{R/2}.

Similarly, a resistance value of memristors arranged along an output line 481 may be set based on a second row vector of the fourth transformation matrix S_{I/2}, and a resistance value of memristors arranged along an output line 482 may be set based on a third row vector of the fourth transformation matrix S_{I/2}. In addition, a resistance value of memristors arranged along an output line 483 may be set based on a fourth row vector of the fourth transformation matrix S_{I/2}.

As described above, in an example, the input processor of the MCA may divide an input signal into a first-half input signal and a second-half input signal, and apply the signals to memristors based on the first-half input signal and the second-half input signal. In this case, a resistance value of the memristors included in the MAC may be set based on a third transformation matrix downsized from a first transformation matrix and a fourth transformation matrix downsized from a second transformation matrix. Thus, it is possible to output a signal associated with each frequency component intensity of the input signal using a smaller number of memristors.

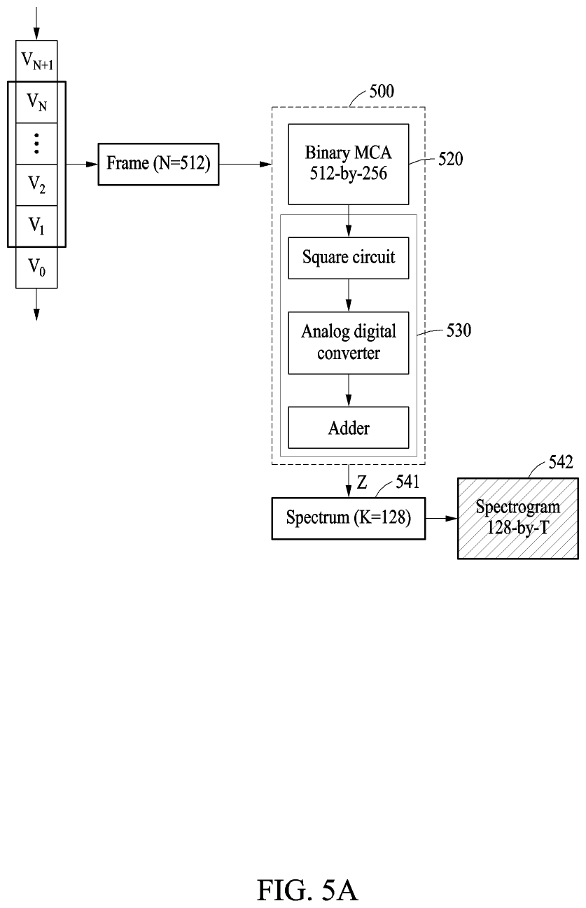

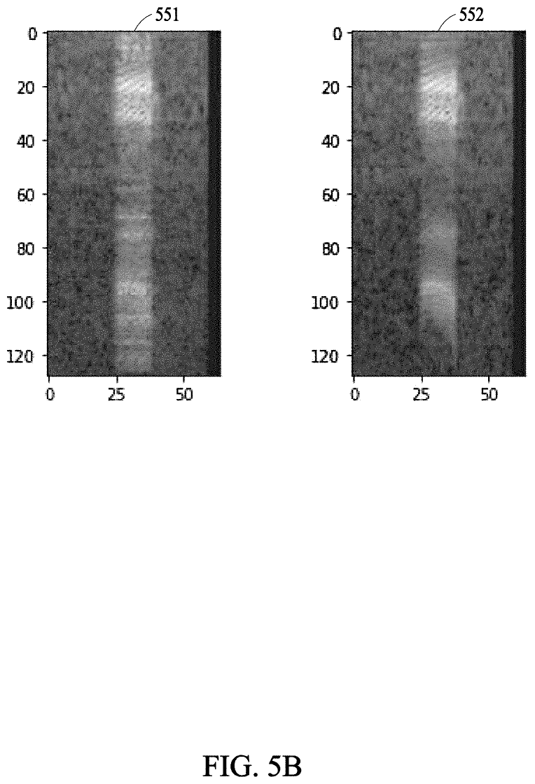

FIGS. 5A and 5B illustrate examples of extracting a spectrogram of a frequency component from an audio file using an MCA circuit.

Assuming that a length of an audio file is one second and a sampling rate is 16 kilohertz (kHz), a total length of the audio file may correspond to 16,000 samples. Through a framing process, a signal corresponding to one frame may be input as an input signal to an MCA circuit 500. One frame may include a predetermined number N of samples.

A frame length may indicate the number N of samples included in one frame. For example, the frame length may be set as 512. That is, one sample may correspond to one input value, and the predetermined number may correspond to the number of samples included in one frame.

The input signal may be input to an MCA 520 through an input processor (not shown). The size of the MCA 520 may be determined by the frame length and the number of frequency components. For example, in a case of an audio file, the frame length may be generally set as 512, and a frequency range to be extracted may be up to 4 kHz excluding a DC component frequency. In this example, the number of frequency components may be calculated as represented by Equation 17 below.

$$Number of frequency characteristics = Frame length \times \frac{Frequency characteristic range}{Sampling rate} \qquad [ Equation 17 ]$$

According to Equation 17 above, the number of frequency characteristics excluding a DC component may be calculated to be 128 which is

$$512 \times \frac{4 KHz}{16 kHz} .$$

That is, the number of frequency characteristics including the DC component may be calculated to be 129.

As described above, a first transformation matrix and a second transformation matrix may each have a matrix of the size of (the number of frequency characteristics×the predetermined number), and may have the size of 129×512 to calculate a frequency component intensity of an input signal including frequency components of a DC component in which a frequency is zero.

When calculating the intensity frequency component of each frequency component excluding a DC frequency component, a first row of each of the first transformation matrix and the second transformation matrix may not be used to set a resistance value of memristors included in the MCA 520. For example, a first row of S_{R} in Equation 8 and a first row of S_{I} in Equation 10 correspond to the DC frequency component, and thus the respective first rows of the first transformation matrix and the second transformation matrix may not be used to set the resistance value of the memristors. In this example, each of the first transformation matrix and the second transformation matrix has the size of 129×512, and the first rows of the first transformation matrix and the second transformation matrix are not used to set the resistance value of the memristors, and thus the MCA 520 may have the size of 512×256, that is, the MCA 520 may include 512×256 memristors.

An outputter 530 of the MCA circuit 500 may square signals output from the MCA 520 through a square circuit, convert an analog signal to a digital signal through an ADC, and output a signal associated with a frequency component intensity through an adder.

A spectrum 541 indicating a frequency component intensity may be calculated for each frame, and a spectrogram 542 may be generated by connecting spectrums generated for frames in time sequence.

The size of the spectrogram 542 may be determined based on the number k of frequency components and the number T of input frames, and more specifically, the spectrogram 542 may have the size of k×T. Here, the number k of frequency components is 128, and thus the spectrogram 542 may have the size of 128×T. The number T of frames may be determined based on a length of an audio signal, a frame length, and a frame step. For example, when the length of the audio signal is 1024, the frame length is 512, and the frame step is 256, a total number T of frames may be 3.

In the example of FIG. 5B, illustrated are spectrograms in a case in which a frame length is 512, the number of input frames is 64, and the number of frequency characteristics is 128. A spectrogram 551 represents a spectrogram result calculated based on the MCA circuit 500 of example embodiments, and has the size of 128×64. A spectrogram 552 represents a spectrogram result stored in advance for an audio signal, and has the size of 128×64. FIG. 5B shows that the spectrogram 551 obtained by the MCA circuit 500 and the prestored spectrogram 552 are similar to each other. In this case, it may be determined that an audio signal corresponding to the spectrogram 551 and an audio signal corresponding to the prestored spectrogram 552 are the same.

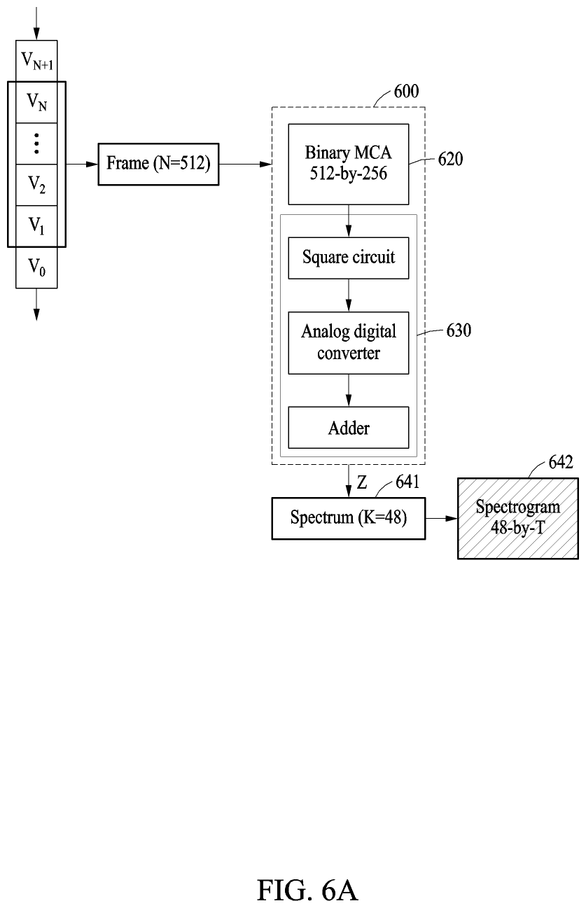

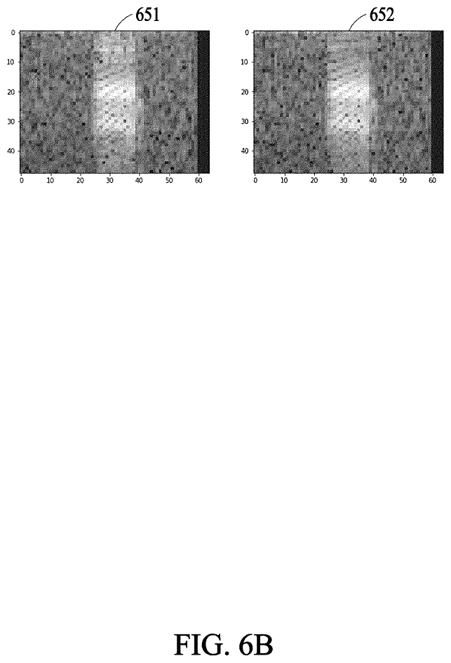

FIGS. 6A and 6B illustrate examples of extracting a spectrogram of a frequency component from an audio file using an MCA circuit.

Assuming that a length of an audio file is one second and a sampling rate is 1.5 kHz, a total length of the audio file may correspond to 16,000 samples. Through a framing process, a signal corresponding to one frame may be applied as an input signal to an MCA circuit 600. One frame may include a predetermined number N of samples. Hereinafter, a frame length set as 512 will be described as an example.

The input signal may be input to an MCA 620 through an input processor (not shown). The size of the MCA 620 may be determined by a frame length and the number of frequency components. For example, in a case of an audio file, a frame length may be generally set as 512, and a frequency range to be extracted may be up to 1.5 kHz excluding a DC component frequency. In this example, the number of frequency components may be calculated to be 48 which is

$$512 \times \frac{1.5 KHz}{16 kHz} ,$$

the number of frequency characteristics excluding a DC component, according to Equation 17 above. That is, the number of frequency characteristics including the DC component may be calculated to be 49.

As described above, a first transformation matrix and a second transformation matrix may each have a matrix of the size of (the number of frequency characteristics×the predetermined number), and may have the size of 49×512 to calculate a frequency component intensity of an input signal including a frequency component of the DC component in which a frequency is zero.

When calculating a frequency component intensity excluding a DC frequency component, a first row of each of the first transformation matrix and the second transformation matrix may not be used to set a resistance value of memristors included in the MCA 620. In this case, the first transformation matrix and the second transformation matrix may each have the size of 49×512, and first rows of the first transformation matrix and the second transformation matrix may not be used to set a resistance value of memristors, and thus the MCA 620 may have the size of 512×96, that is, the MCA 620 may include 512×96 memristors.

An outputter 630 of the MCA circuit 600 may square signals output from the MCA 620 through a square circuit, convert an analog signal to a digital signal through an ADC, and output a signal associated with a frequency component intensity through an adder.

A spectrum 641 indicating the frequency component intensity may be calculated for each frame, and a spectrogram 642 may be finally generated by connecting spectrums generated for frames in time sequence.

The size of the spectrogram 642 may be determined based on the number k of frequency components and the number T of input frames. More specifically, the number k of frequency components is 48, and thus the spectrogram 642 may have the size of 48×T. In the example of FIG. 6B, illustrated are spectrograms in a case in which a frame length is 512, the number of input frames is 64, and the number of frequency characteristics is 48. A spectrogram 651 represents a spectrogram result calculated based on the MCA circuit 600 of example embodiments, and has the size of 48×64. A spectrogram 652 represents a spectrogram result stored in advance for an audio signal, and has the size of 48×64. FIG. 6B shows that the spectrogram 651 obtained by the MCA circuit 600 and the prestored spectrogram 652 are similar to each other. In this case, it may be determined that an audio signal corresponding to the spectrogram 651 and an audio signal corresponding to the prestored spectrogram 652 are the same.

The MCA circuit 100, input processor 110, MCA 120, outputter 130, and other apparatuses, devices, units, modules, and components described herein are implemented by hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, multiple-instruction multiple-data (MIMD) multiprocessing, a controller and an arithmetic logic unit (ALU), a DSP, a microcomputer, an application-specific integrated circuit (ASIC), a field programmable gate array (FPGA), a programmable logic unit (PLU), a central processing unit (CPU), a graphics processing unit (GPU), a neural processing unit (NPU), or any other device capable of responding to and executing instructions in a defined manner.

The software may include a computer program, a piece of code, an instruction, or some combination thereof, to independently or uniformly instruct or configure the processing device to operate as desired. Software and data may be embodied permanently or temporarily in any type of machine, component, physical or pseudo equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In an example, the instructions or software includes at least one of an applet, a dynamic link library (DLL), middleware, firmware, a device driver, an application program storing the method of operating the MCA circuit. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), magnetic RAM (MRAM), spin-transfer torque(STT)-MRAM, static random-access memory (SRAM), thyristor RAM (T-RAM), zero capacitor RAM (Z-RAM), twin transistor RAM (TTRAM), conductive bridging RAM(CBRAM), ferroelectric RAM (FeRAM), phase change RAM (PRAM), resistive RAM(RRAM), nanotube RRAM, polymer RAM (PoRAM), nano floating gate Memory(NFGM), holographic memory, molecular electronic memory device), insulator resistance change memory, dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and providing the instructions or software and any associated data, data files, and data structures to a processor or computer so that the processor or computer can execute the instructions. In an example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A memristor crossbar array (MCA) circuit, comprising:
an input processor configured to receive an input signal corresponding to a predetermined number of input values and to apply the input signal to memristors arranged along input lines;
an MCA comprising the memristors having resistance values based on at least one transformation matrix comprising binary element values; and
an outputter configured to output a frequency component intensity of the input signal based on a signal that is output from each of output lines on which the memristors are arranged, in response to the input signal being applied to the memristors.

2. The MCA circuit of claim 1, wherein one row vector of the at least one transformation matrix corresponds to a frequency component.

3. The MCA circuit of claim 1, wherein the at least one transformation matrix comprises a first transformation matrix and a second transformation matrix, and
wherein the first transformation matrix and the second transformation matrix comprise a number of column vectors corresponding to the predetermined number and a number of row vectors corresponding to the number of frequency components of the input signal.

4. The MCA circuit of claim 1, further comprising:
a memory write circuit configured to set the resistance values of the memristors of the MCA,
wherein the memory write circuit is further configured to set a resistance value of a memristor from among the memristors to an element value of a corresponding element of a first transformation matrix, and to set a resistance value of a memristor from among the memristors to an element value of a corresponding element of a second transformation matrix.

5. The MCA circuit of claim 3, wherein elements of a first reference row vector of the first transformation matrix have a first value, and an element of a row vector different from the first reference row vector of the first transformation matrix has a value that is based on element values of a second reference row vector of the first transformation matrix.

6. The MCA circuit of claim 5, wherein a target element of the row vector different from the first reference row vector of the first transformation matrix has a same value as a value of an element in an order corresponding to a remainder obtained by dividing, by the predetermined number, a product obtained by multiplying a value that indicates a row order of the row vector comprising the target element from among a plurality of row vectors comprising the first transformation matrix and a value indicating an order of the target element in the row vector comprising the target element, from among elements belonging to the second reference row vector of the first transformation matrix.

7. The MCA circuit of claim 3, wherein elements of a second reference row vector of the second transformation matrix comprises elements of a second reference row vector of the first transformation matrix that are shifted by ¼ of the predetermined number.

8. The MCA circuit of claim 7, wherein a target element of a row vector different from a first reference row vector of the second transformation matrix has a same value as a value of an element in an order corresponding to a remainder obtained by dividing, by the predetermined number, a product obtained by multiplying a value that indicates a row order of the row vector comprising the target element from among a plurality of row vectors comprising the second transformation matrix and a value indicating an order of the target element in the row vector comprising the target element, from among elements belonging to the second reference row vector of the second transformation matrix.

9. The MCA circuit of claim 1, wherein an output line that outputs a signal associated with a real part intensity of a frequency component and an output line that outputs a signal associated with an imaginary part intensity of the frequency component are adjacent to each other in the MCA.

10. The MCA circuit of claim 1, wherein the outputter comprises:
a plurality of adders configured to add a signal indicating a square of a real part intensity of each frequency component and a signal indicating a square of an imaginary part intensity of the each frequency component from among digital signals corresponding to a square of an output signal of each of the output lines, and to output a signal associated with an intensity of a corresponding frequency component.

11. The MCA circuit of claim 3, wherein the input processor is configured to:
apply, to a memristor, a sum signal obtained by adding a first-half input signal of the input signal and a second-half input signal of the input signal and a subtraction signal obtained by subtracting the second-half input signal from the first-half input signal,
wherein the at least one transformation matrix comprises a third transformation matrix and a fourth transformation matrix,
wherein the third transformation matrix and the fourth transformation matrix have a number of column vectors corresponding to half of the predetermined number and have a number of row vectors corresponding to the number of frequency components of the input signal.

12. The MCA circuit of claim 11, wherein the third transformation matrix is determined based on the row vectors of the first transformation matrix, and the fourth transformation matrix is determined based on the row vectors of the second transformation matrix.

13. A processor-implemented method of operating a memristor crossbar array (MCA) circuit, comprising:
receiving an input signal corresponding to a predetermined number of input values, and applying the input signal to memristors arranged along input lines;
setting resistance values of the memristors comprised in an MCA based on at least one transformation matrix comprising binary element values; and
outputting a frequency component intensity of the input signal based on a signal that is output from each of output lines on which the memristors are arranged, in response to the input signal being applied to the memristors.

14. The method of claim 13, wherein one row vector of the at least one transformation matrix corresponds to a frequency component.

15. The method of claim 13, wherein the at least one transformation matrix comprises a first transformation matrix and a second transformation matrix, and
wherein the first transformation matrix and the second transformation matrix comprise a number of column vectors corresponding to the predetermined number and a number of row vectors corresponding to the number of frequency components of the input signal.

16. The method of claim 13, wherein the setting of the resistance values of the memristors comprises:
setting a resistance value of a memristor from among the memristors to an element value of a corresponding element of a first transformation matrix; and
setting a resistance value of a memristor from among the memristors to an element value of a corresponding element of a second transformation matrix.

17. The method of claim 15, wherein elements of a first reference row vector of the first transformation matrix have a first value, and an element of a row vector different from the first reference row vector of the first transformation matrix has a value that is based on element values of a second reference row vector of the first transformation matrix.

18. The method of claim 17, wherein a target element of the row vector different from the first reference row vector of the first transformation matrix has a same value as an element value of an element in an order corresponding to a remainder obtained by dividing, by the predetermined number, a product obtained by multiplying a value that indicates a row order of the row vector comprising the target element from among a plurality of row vectors comprising the first transformation matrix and a value indicating an order of the target element in the row vector comprising the target element, from among elements belonging to the second reference row vector of the first transformation matrix.

19. The method of claim 15, wherein elements of a second reference row vector of the second transformation matrix comprises elements of a second reference row vector of the first transformation matrix that are shifted by ¼ of the predetermined number.

20. The method of claim 15, wherein the applying to the memristors comprises:
applying, to a memristor, a sum signal obtained by adding a first-half input signal of the input signal and a second-half input signal of the input signal and a subtraction signal obtained by subtracting the second-half input signal from the first-half input signal,
wherein the at least one transformation matrix comprises a third transformation matrix and a fourth transformation matrix,
wherein the third transformation matrix and the fourth transformation matrix have a number of column vectors corresponding to half of the predetermined number and have a number of row vectors corresponding to the number of frequency components of the input signal.

21. A memristor crossbar array (MCA) circuit, comprising:
an MCA comprising memristors arranged along output lines and having resistance values based on at least one transformation matrix;
a square circuit configured to square a signal output from each of the output lines;
an analog-to-digital converter configured to convert the squared signal output to a digital signal; and
a plurality of adders configured to output a signal associated with an intensity of a corresponding frequency component,
wherein the at least one transformation matrix comprises a first transformation matrix and a second transformation matrix, each having a number of column vectors corresponding to a number of input values of an input signal and a number of row vectors corresponding to a number of frequency components of the input signal.

22. The MCA circuit of claim 21, wherein:
an element corresponding to an i^{th} row and a j^{th} column of the first transformation matrix is mapped to a memristor arranged on a j^{th} row and an i^{th} column of a first memristor set of the MCA; and
an element corresponding to an i^{th} row and a j^{th} column of the second transformation matrix is mapped to a memristor arranged on a j^{th} row and an (i-1)^{th} column of a second memristor set of the MCA,
wherein i is an integer greater than or equal to 1 and less than or equal to the number of frequency components, and j is an integer greater than or equal to 1 and less than or equal to the number of the input values.

23. The MCA circuit of claim 21, wherein the at least one transformation matrix comprises a third transformation matrix and a fourth transformation matrix each having a number of column vectors corresponding to half of the number of the input values and having a number of row vectors corresponding to the number of frequency components of the input signal.
